(19) United States
(12) Patent Application Publication
(10) Pub. No.: US 2026/0233440 A1
(43) Pub. Date: Aug. 13, 2026

(54) ADJUSTMENT METHOD, IMPRINT METHOD, ARTICLE MANUFACTURING METHOD, AND IMPRINT APPARATUS

(71) Applicant: CANON KABUSHIKI KAISHA, Tokyo (JP)

(72) Inventor: Masato Ito, Tochigi (JP)

(21) Appl. No.: 19/646,002

(22) Filed: Apr. 13, 2026

Related U.S. Application Data
(63) Continuation of application No. PCT/JP2024/035091, filed on Oct. 1, 2024.

(30) Foreign Application Priority Data
Nov. 1, 2023 (JP) 2023-187901

(51) Int. Cl. B29C 43/58; B29C 43/18; G01B 11/06; G03F 7/00; G03F 9/00

(52) U.S. Cl. CPC B29C 43/58; B29C 43/18; G01B 11/0608; G03F 7/0002; G03F 9/7042; G03F 9/7084; G03F 9/7088; G03F 9/7092; B29C 2043/5833

(57) ABSTRACT

The present disclosure provides an adjustment method for an imprint apparatus that forms a pattern to an imprint material on a substrate held by a stage, by using a mold held by a mold holder, the method comprising: estimating a position of a member held by the mold holder, as a first position, based on a result of detecting a relative position between a mark on the member and a mark on the stage with a detector; estimating a position of the member, as a second position, based on a result of measuring a surface height distribution of the member held by the mold holder with a measurement device; and determining an offset of the measurement device based on the estimated first and second positions.

### CROSS-REFERENCE TO RELATED APPLICATIONS

This application is a Continuation of International Patent Application No. PCT/JP2024/035091, filed October 1, 2024, which claims the benefit of Japanese Patent Application No. 2023-187901 filed November 1, 2023, which is hereby incorporated by reference herein in its entirety.

### BACKGROUND

### Field of the Technology

The present disclosure relates to an adjustment method, an imprint method, an article manufacturing method, and an imprint apparatus.

### DESCRIPTION OF THE RELATED ART

With growth in demand for the miniaturization of semiconductor devices, MEMS, and the like, much attention has been paid to microfabrication technology of shaping an uncured imprint material on a substrate with a mold and forming the pattern of the imprint material on the substrate in addition to conventional photolithography techniques. This technology is also called imprint technology and can be used to form microstructures on the several nanometer order on substrates. For example, as one of the imprint techniques, a photo-curing method is available. An imprint apparatus using this photo-curing method is configured to cure an imprint material (photo-curable resin) supplied onto a substrate (wafer) while a mold is in contact with the imprint material and separate (release) the mold from the cured imprint material. This makes it possible to form the pattern formed of the cured product of the imprint material on the substrate.

A mold used in an imprint apparatus is provided with a convex portion called a mesa portion, and a pattern is formed on the mesa portion. The imprint apparatus measures the surface height distribution of a mold and controls the position, inclination, and rotation of the mesa portion of the mold based on the measurement result in order to accurately form the pattern of the imprint material on the substrate. Japanese Patent No. 6,029,268 discloses an imprint apparatus including, on a substrate stage, a measurement unit that measures the surface height distribution of a mold. This measurement unit can measure the surface height distribution of the mold by sequentially detecting the distance to the mold (that is, the surface height of the mold) while moving in a planar direction accompanying the movement of the substrate stage.

In an imprint apparatus, a measurement unit that measures the surface height distribution of a mold is sometimes offset in a case where the measurement unit is attached at a position offset from a predetermined position on a substrate stage, or an optical member is incorporated in the measurement unit at a position offset from a predetermined position. In this case, it is difficult to accurately control the position, inclination, and rotation of the mesa portion of the mold based on the measurement result obtained by the measurement unit, and hence there is a need to accurately acquire the offset of the measurement unit.

Japanese Patent No. 6,029,268 discloses a method of acquiring the offset of a measurement unit with reference to an alignment scope that detects a mark on a mold (mesa portion). This method sets, as a reference, the position of the mesa portion specified by detecting the mark on the mesa portion with an alignment scope and acquires, as the offset of the measurement unit, the shift of the position of the mesa portion specified by measuring the surface height distribution of the mold with the measurement unit. However, in general, in the imprint apparatus, the alignment scope and the measurement unit are driven by different driving systems, and the positional relationship between them is not guaranteed. For this reason, the method disclosed in Japanese Patent No. 6,029,268 cannot satisfactorily and accurately acquire the offset of the measurement unit.

### SUMMARY

Present disclosure provides a technique advantageous in accurately acquiring the offset of a measurement unit that measures the surface height distribution of a mold.

According to one aspect of the present disclosure, there is provided an adjustment method for an imprint apparatus that forms a pattern to an imprint material on a substrate held by a stage, by using a mold held by a mold holder, the method comprising: estimating a position of a member held by the mold holder, as a first position, based on a result of detecting a relative position between a mark on the member and a mark on the stage with a detector; estimating a position of the member, as a second position, based on a result of measuring a surface height distribution of the member held by the mold holder with a measurement device; and determining an offset of the measurement device based on the estimated first and second positions.

Features of the present disclosure will become apparent from the following description of exemplary embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing a configuration example of an imprint apparatus according to an embodiment of the present disclosure.

FIG. 2 is a flowchart showing imprint processing according to an embodiment of the present disclosure.

FIG. 3 is a view for explaining the offset of a second measurement unit.

FIG. 4 is a flowchart showing adjustment processing according to an embodiment of the present disclosure.

FIGS. 5A and 5B are views showing an embodiment associated with the configuration of an adjustment member (mold) and the measurement of the surface height distribution.

FIGS. 6A to 6F are views for explaining an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which a plane parallel to a surface of a substrate is defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes.

An embodiment according to the present disclosure will be described below. An imprint apparatus is a lithography apparatus that shapes an imprint material (composition) on a substrate by using a mold and can be used in a lithography step as a manufacturing step for a device such as a semiconductor device or a magnetic storage medium. The imprint apparatus performs the processing of bringing a mold into contact with an uncured imprint material supplied onto a substrate and applying curing energy to the imprint material to form, on the substrate, the pattern of the cured product onto which the concave/convex pattern of the mold has been transferred. Such processing is called imprint processing and performed for the pattern formation region of a substrate. For example, the imprint apparatus is used to manufacture a device such as a semiconductor device as an article. This apparatus shapes an uncured imprint material on a wafer (substrate) as a substrate to be processed by using a mold and forms the pattern of the imprint material on the wafer. In addition to the above operation, the imprint apparatus can execute the processing of forming a pattern portion on the convex portion of a blank mold to manufacture a plurality of replica molds having the same pattern portion.

### Configuration of Imprint Apparatus

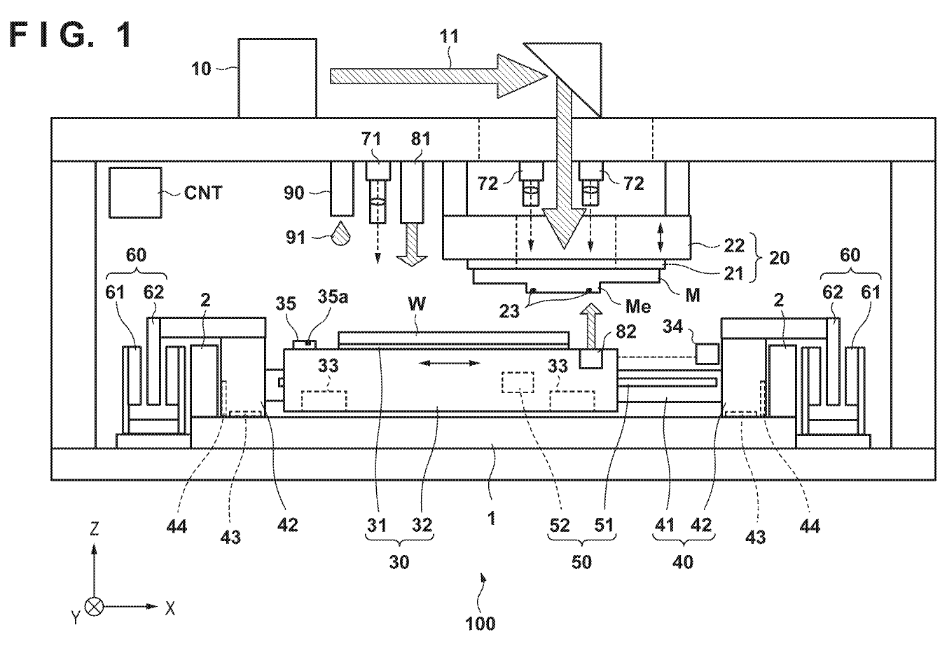

FIG. 1 is a schematic view showing a configuration example of an imprint apparatus 100 according to the present embodiment. The imprint apparatus 100 according to the present embodiment can be used for the preparation of a replica mold and/or the manufacture of a semiconductor device or the like. In a case where the imprint apparatus 100 is used for the preparation of a replica mold, a master mold on which a pattern is formed is used as a mold M, and a blank mold before the formation of a pattern is used as a substrate W. In this case, part (convex portion) of the blank mold as the substrate W becomes a pattern formation region for which imprint processing is performed. In contrast to this, in a case where the imprint apparatus 100 is used for the manufacture of a semiconductor device or the like, a replica mold on which a pattern is formed is used as the mold M, and a semiconductor wafer (for example, a silicon wafer) is used as the substrate W. In this case, each of a plurality of shot regions on the semiconductor wafer as the substrate W becomes a pattern formation region for which imprint processing is performed. The following describes an example in which the imprint apparatus 100 is used for the preparation of a replica mold. However, the apparatus configuration and processing contents in this case are the same as those in a case where the imprint apparatus 100 is used for the manufacture of a semiconductor device or the like. The following describes an example in which the imprint apparatus 100 uses a photo-curing method of curing an imprint material by irradiation with light.

The mold M generally has a square outer peripheral shape and is prepared using a material, such as silica glass, which can transmit light 11 (for example, ultraviolet light). A partial region of a surface of the mold M which faces the substrate W is provided with, for example, a mesa portion Me formed into a convex shape having a stepped portion. A concave/convex pattern to be transferred to an imprint material on the substrate W is formed on a surface of the mesa portion Me which is located on the substrate W side. That is, the mesa portion Me may be understood as a pattern portion on which the concave/convex pattern to be transferred to the imprint material on the substrate W is formed. In addition, the surface of the mesa portion Me which is located on the substrate W side is provided with an alignment mark 23 that can be detected (observed) with a second detection unit 72 (alignment scope) (to be described later).

As the substrate W, glass, ceramic, a metal, a semiconductor, a resin, or the like is used. As necessary, a member made of a material different from that of the substrate may be formed on its surface as needed. More specifically, in a case where the imprint apparatus 100 is used for the preparation of a replica mold, a blank mold made of silica glass is used as the substrate W. In contrast to this, in a case where the imprint apparatus 100 is used for the manufacture of a semiconductor device or the like, a silicon wafer, a compound semiconductor wafer, or silica glass can be used as the substrate W.

The imprint apparatus 100 can include, for example, a light irradiation unit 10, a mold holding unit 20 that holds the mold M, a substrate holding unit 30 that holds the substrate W, a driving mechanism (a beam member 40, an X driving unit 50, and a Y driving unit 60) that drives the substrate holding unit 30, and a control unit CNT. The imprint apparatus 100 can include a first detection unit 71 that detects the position of an alignment mark on the substrate W and a second detection unit 72 that detects the relative position between the alignment mark 23 on the mold M and the alignment mark on the substrate W. The imprint apparatus 100 can include a first measurement unit 81 that measures the surface height distribution of the substrate W and a second measurement unit 82 that measures the surface height distribution of the mold M. Although not shown in FIG. 1, the imprint apparatus 100 may include a mold transfer mechanism that transfers the mold M and a substrate transfer mechanism that transfers the substrate W.

The light irradiation unit 10 cures an imprint material on the substrate W by irradiating the imprint material with light 11 (for example, ultraviolet light) while the mold M is in contact with the imprint material in imprint processing. The light irradiation unit 10 can include, for example, a light source and an optical element. The optical element adjusts the light emitted from the light source into light suitable for the irradiation of the imprint material.

The mold holding unit 20 (imprint head) is configured to be able to hold the mold M and move in the Z direction. More specifically, the mold holding unit 20 can include a mold chuck 21 that holds the mold M by vacuum suction and a mold driving mechanism 22 that drives the mold M by driving the mold chuck 21. The mold holding unit 20 drives the mold M in the Z direction so as to perform the contact operation of bringing the mold M into contact with an imprint material on the substrate W and the mold releasing operation of releasing the mold M from the cured imprint material on the substrate W. Note, however, that the mold holding unit 20 may be configured to have a position adjustment function for adjusting the position of the mold M in, in addition to the Z direction, the X direction, the Y direction, and rotating directions about the respective axes (the θX, θY, and θZ directions) and a tilt function for correcting the inclination of the mold M. Note that although the contact operation and the mold releasing operation in imprint processing may be performed by causing the mold holding unit 20 to drive the mold M in the Z direction, the operations may be performed by causing the substrate holding unit 30 to drive the substrate W in the Z direction. Alternatively, an imprint operation and a mold releasing operation may be performed by causing both the mold holding unit 20 and the substrate holding unit 30 to relatively drive the mold M and the substrate W in the Z direction.

The substrate holding unit 30 is configured to be able to hold and move the substrate W in the X and Y directions. The substrate holding unit 30 can include a substrate chuck 31 that holds the substrate W by vacuum suction and a stage 32 that supports and move the substrate chuck 31 on a platen 1 in the X and Y directions. The substrate holding unit 30 is driven in the X and Y directions by a driving mechanism including the beam member 40, the X driving unit 50, and the Y driving unit 60 to align the mold M with the substrate W. Note, however, that the substrate holding unit 30 may be configured to include, for example, a position adjustment function for adjusting the position of the substrate W in the Z direction and rotating directions about the respective axes (the θX, θY, and θZ directions) as well as in the X and Y directions or a tilt function for correcting the inclination of the substrate W.

The bottom portion (lower surface) of the stage 32 is provided with a bottom driving mechanism 33 for positioning the stage 32 in the Z direction. The imprint apparatus 100 is preferably configured to drive the stage 32 with a large stroke in the X and Y directions fast and accurately by reducing the friction and wear between the stage 32 and the platen 1. Accordingly, the stage 32 is kept floated from the reference surface (upper surface) of the platen 1 by several μm to several tens of μm by the bottom driving mechanism 33. For example, the bottom driving mechanism 33 has an air guide and can position the stage 32 in the Z direction by forming a gap between the stage 32 and the platen 1 by ejecting a gas toward the reference surface (upper surface) of the platen 1 from the air guide. The bottom driving mechanism 33 may have a suction mechanism for making the stage 32 and the platen 1 suction each other, such as a cylinder mechanism using air, a magnet, and the pressure of a fluid in order to stabilize the position of the stage 32 in the Z direction.

The beam member 40 is a member extending in the X direction to guide the movement of the stage 32 in the X direction and is placed so as to extend through an opening provided in the stage 32. The beam member 40 can include a guide portion 41 that guides the movement of the stage 32 in the X direction and a support portion 42 that supports the guide portion 41 at its both ends. A mover 62 of the Y driving unit 60 (to be described later) is fixed to the support portion 42. The support portion 42 is provided with air guides 43 and 44. The air guide 43 ejects a gas toward the platen 1 to form a gap between the support portion 42 and the platen 1 and position the beam member 40 (the support portion 42) in the Z direction. The air guide 44 ejects a gas toward a fixing member 2 fixed to the platen 1 to form a gap between the support portion 42 and the fixing member 2 and position the beam member 40 (the support portion 42) in the X direction. The fixing member 2 extends in the Y direction on the platen 1.

The X driving unit 50 is a mechanism that drives the substrate holding unit 30 and the substrate W in the X direction by driving the stage 32 in the X direction along the beam member 40. In the present embodiment, the X driving unit 50 can be implemented by a linear motor having a stator 51 and a mover 52. The stator 51 includes a plurality of coils arrayed along the X direction and is provided on the guide portion 41 of the beam member 40. The mover 52 includes a permanent magnet and is provided on the stage 32 (more specifically, the inner surface of the opening through which the guide portion 41 extends).

The Y driving unit 60 is a mechanism that drives the substrate holding unit 30 and the substrate W in the Y direction by driving the beam member 40 in the Y direction. In the present embodiment, the Y driving unit 60 can be implemented by a linear motor having a stator 61 and a mover 62. The stator 61 has a plurality of coils arrayed in the Y direction. The mover 62 includes a permanent magnet and is fixed to the support portion 42 of the beam member 40.

A position measurement unit 34 can measure the position of the substrate holding unit 30 (the stage 32). The position measurement unit 34 measures the position of the stage 32 in a coordinate system (to be sometimes referred to as the stage coordinate system hereinafter) for controlling the position of the stage 32. In the present embodiment, the position measurement unit 34 can be implemented by, for example, a laser interferometer but may be implemented by an encoder. This enables the control unit CNT to control the position of the stage 32 in the stage coordinate system based on the measurement result obtained by the position measurement unit 34. Note that the stage coordinate system can be understood as a reference coordinate system serving as a reference for controlling the position of the stage 32 or a measurement coordinate system for measuring the position of the stage 32.

A reference plate 35 is mounted on the stage 32 of the substrate holding unit 30. The reference plate 35 includes an alignment mark 35a that is detected by the first detection unit 71 and the second detection unit 72 (which are described later). The alignment mark 35a may be provided to be commonly used by the first detection unit 71 and the second detection unit 72 or may be provided to be individually used by each of the first detection unit 71 and the second detection unit 72.

The first detection unit 71 is an alignment detection system (alignment scope) that detects the position of an alignment mark on the substrate W held by the substrate holding unit 30 (the stage 32). The first detection unit 71 is sometimes called an alignment detection system (substrate alignment scope). The control unit CNT can specify the position of the substrate W (pattern formation region) based on the position of the alignment mark on the substrate W which is detected by the first detection unit 71.

The second detection unit 72 is an alignment detection system (alignment scope) that detects the relative position between the alignment mark 23 on the mold M held by the mold holding unit 20 and the alignment mark on the substrate W (pattern formation region) held by the substrate holding unit 30. The second detection unit 72 is sometimes called a mold alignment detection system (mold alignment scope). The control unit CNT can control the alignment between the mold M (the mesa portion Me) and the substrate W (pattern formation region) based on the relative position between the alignment mark 23 on the mold M detected by the second detection unit 72 and the alignment mark on the substrate W. In this case, the imprint apparatus 100 may include a plurality of second detection units 72. In this case, it is possible to simultaneously detect a pair of the alignment mark 23 on the mold M and the alignment mark on the substrate W at a plurality of portions. Note that in the following description, an alignment mark is sometimes simply referred to as a mark.

The first measurement unit 81 measures the surface height distribution of the substrate W held by the substrate holding unit 30. More specifically, the first measurement unit 81 can include a sensor that detects the distance to the surface of the substrate W in the Z direction (the surface height of the substrate W). The first measurement unit 81 then can measure the surface height distribution of the substrate W by sequentially detecting the surface height of the substrate W while the substrate W is moved in the X and Y directions by the substrate holding unit 30 (the stage 32) below the first measurement unit 81.

The second measurement unit 82 is mounted on the stage 32 of the substrate holding unit 30 and measures the surface height distribution of the mold M held by the mold holding unit 20. More specifically, the second measurement unit 82 can include a sensor that detects the distance to the surface of the mold M in the Z direction (that is, the surface height of the mold M). The second measurement unit 82 then can measure the surface height distribution of the mold M by sequentially detecting the surface height of the mold M while moving below the mold M accompanying the movement of the substrate holding unit 30 (the stage 32).

In this case, the second measurement unit 82 can incorporate a configuration including a measurement light source (for example, a laser irradiation unit), an image capturing element (sensor), and an analysis mechanism. The second measurement unit 82 having such a configuration makes the light (laser) emitted from the measurement light source to the mold M return to the second measurement unit 82 upon being reflected by the surface of the mold M. The image capturing element such as a CCD observes (detects) this return light, and the analysis mechanism calculates the distance (to be sometimes referred to as a gap amount hereinafter) to the mold M. Gap amount detection methods in the second measurement unit 82 include, for example, a method of detecting a gap amount based on the position of return light when the light enters obliquely with respect to the measurement direction and a method of detecting a gap amount based on the interference fringes between return light and reference light. In the method of detecting a gap amount based on interference fringes, beam spots of reference light have various shapes such as circular shapes and elliptic shapes and various diameters between 10 μm or more and 1,000 μm or less. The average of detection values within this beam spot diameter range is a gap amount.

A supply unit 90 (dispenser) supplies an imprint material 91 in the form of a plurality of droplets onto the substrate W. The supply unit 90 may be understood as a liquid discharge head that discharges (ejects) the imprint material 91 in the form of a plurality of droplets to the substrate W. For example, while the substrate W is moved in the X and Y directions relative to the supply unit 90 by the substrate holding unit 30 (the stage 32) below the supply unit 90, the supply unit 90 is made to discharge the imprint material 91 in the form of a plurality of droplets. This makes it possible to supply the imprint material 91 in the form of a plurality of droplets onto the substrate W (pattern formation region).

As the imprint material 91 supplied onto the substrate W by the supply unit 90, a curable composition (to be also referred to as a resin in an uncured state hereinafter) to be cured by receiving curing energy is used. As the curing energy, electromagnetic waves, heat, or the like is used. The electromagnetic waves include, for example, light such as infrared light, visible light, or ultraviolet light selected from the wavelength range of 10 nm (inclusive) to 1 mm (inclusive). The curable compositions are compositions cured by light irradiation or heating. Among these, the photo-curable composition cured by light irradiation may contain at least a polymerizable compound and a photopolymerization initiator and may contain a nonpolymerizable compound or a solvent, as needed. The nonpolymerizable compound is at least one type of material selected from the group consisting of a sensitizer, a hydrogen donor, an internal mold release agent, a surfactant, an antioxidant, a polymer component, and the like. The imprint material 91 is supplied in the form of a film on the substrate by a spin coater or slit coater. Alternatively, the imprint material 91 may be provided on the substrate in the form of droplets or in the form of an island or film formed by connecting a plurality of droplets by a liquid injection head. The viscosity (the viscosity at 25°C) of the imprint material 91 is, for example, 1 mPa∙s (inclusive) to 100 mPa∙s (inclusive).

The control unit CNT is implemented by, for example, a computer (information processing apparatus) having a processor such as a central processing unit (CPU) and a storage unit such as a memory. The control unit CNT controls imprint processing for the substrate W by controlling the operation of each unit of the imprint apparatus 100 and acquiring values obtained by various sensors (the detection units 71 and 72 and the measurement units 81 and 82).

### Imprint Processing

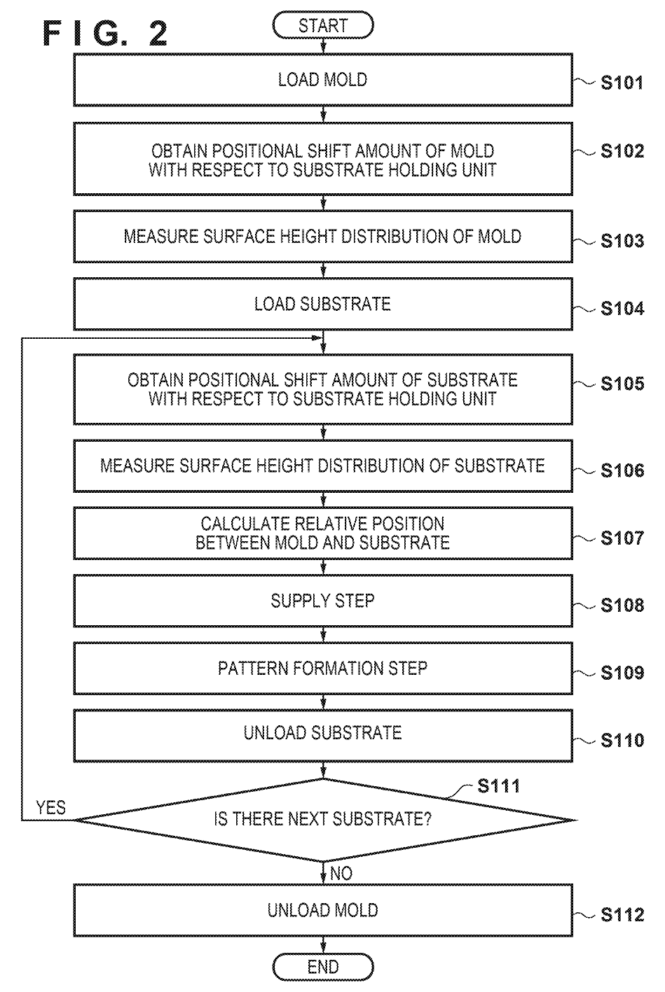

The imprint processing executed by the imprint apparatus 100 described above will be described next. FIG. 2 is a flowchart showing the imprint processing according to the present embodiment. The control unit CNT can execute the imprint processing shown in the flowchart of FIG. 2 by comprehensively controlling the respective units of the imprint apparatus 100.

In step S101, the control unit CNT causes the mold transfer mechanism (not shown) to load the mold M into the mold holding unit 20 and causes the mold holding unit 20 (the mold chuck 21) to hold the mold M.

In step S102, the control unit CNT obtains the positional shift amount (X/Y-direction, θZ-direction, and magnification components) of the mesa portion Me of the mold M with respect to the substrate holding unit 30 (the stage 32). The positional shift amount of the mesa portion Me with respect to the substrate holding unit 30 may be understood as the position of the mesa portion Me in the stage coordinate system.

More specifically, first of all, the control unit CNT causes the reference plate 35 to retreat outside the detection viewing field of the second detection unit 72 by moving the substrate holding unit 30. The control unit CNT causes the mold holding unit 20 to move the mold M so as to place the mark 23 on the mesa portion Me of the mold M at the height of the focus surface of the second detection unit 72. In this state, the control unit CNT causes the second detection unit 72 to detect the position of the mark 23 on the mesa portion Me. The control unit CNT then causes the mold holding unit 20 to move the mold M in the Z direction so as to cause the mark 23 on the mesa portion Me to retreat from the focus surface of the second detection unit 72. The control unit CNT moves the substrate holding unit 30 so as to place the upper surface of the reference plate 35 at the height of the focus surface of the second detection unit 72 and place the mark 35a on the reference plate 35 within the detection viewing field of the second detection unit 72. In this state, the control unit CNT causes the second detection unit 72 to detect the position of the mark 35a on the reference plate 35.

This enables the control unit CNT to obtain the positional shift amount of the mesa portion Me with respect to the substrate holding unit 30 (the stage 32) based on the position of the mark on the mesa portion Me detected by the second detection unit 72 and the position of the mark 35a on the reference plate 35. In addition, the control unit CNT can obtain not only the X/Y-direction, but also the θZ-direction, and magnification components of the positional shift amount of the mesa portion Me with respect to the substrate holding unit 30 by causing the second detection unit 72 to detect the position of the mark 23 at two or more portions of the mesa portion Me. This positional shift amount can be calculated by using the least squares method or the like.

In step S103, the control unit CNT causes the second measurement unit 82 to measure the surface height distribution of the mold M. More specifically, the control unit CNT causes the second measurement unit 82 to detect the distance to the surface of the mold M (the surface height of the mold M) while moving the second measurement unit 82 in the X and Y directions with respect to the mold M by moving the substrate holding unit 30 (the stage 32) in the X and Y directions. This enables the second measurement unit 82 to measure the surface height distribution of the mold M. In addition, the control unit CNT can acquire the position, height, inclination, shape, and the like of the mesa portion Me based on the surface height distribution of the mold M measured by the second measurement unit 82.

In this case, detection target portions at which surface heights are detected by the second measurement unit 82 are sometimes set on the surface of the mold M. If, for example, the second measurement unit 82 is caused to detect a surface height at a portion where a concave portion of a concave/convex pattern is provided, a detection error sometimes occurs. Accordingly, a plurality of detection target portions are set at portions where detection errors hardly occur. The control unit CNT causes the second measurement unit 82 to detect a surface height at each of a plurality of detection target portions on the surface of the mold M while moving the substrate holding unit 30 (the stage 32) step by step. This enables the second measurement unit 82 to measure the surface height distribution of the mold M based on the surface height detected at each of the plurality of detection target portions.

In step S104, the control unit CNT causes the substrate transfer mechanism (not shown) to load the substrate W into the substrate holding unit 30 and causes the substrate holding unit 30 (the substrate chuck 31) to hold the substrate W.

In step S105, the control unit CNT obtains the positional shift amount (X/Y-direction, θZ-direction, and magnification components) of the substrate W with respect to the substrate holding unit 30. The positional shift amount of the substrate W with respect to the substrate holding unit 30 may be understood as the position of the substrate W in the stage coordinate system. More specifically, the control unit CNT causes the first detection unit 71 to detect the position of each of the plurality of marks on the substrate W while causing the substrate holding unit 30 (the stage 32) to move the substrate W below the first detection unit 71. In addition, the control unit CNT causes the first detection unit 71 to detect the position of the mark 35a on the reference plate 35. This enables the control unit CNT to obtain the positional shift amount (X/Y-direction, θZ-direction, and magnification components) of the substrate W with respect to the substrate holding unit 30 based on the position of each mark on the substrate W detected by the first detection unit 71 and the position of the mark 35a on the reference plate 35.

In step S106, the control unit CNT causes the first measurement unit 81 to measure the surface height distribution of the substrate W. More specifically, the control unit CNT causes the first measurement unit 81 to detect the distance to the surface of the substrate W (the surface height of the substrate W) while moving the substrate W in the X and Y directions with respect to the first measurement unit 81 by moving the substrate holding unit 30 (the stage 32) in the X and Y directions. This enables the first measurement unit 81 to measure the surface height distribution of the substrate W. In addition, the control unit CNT can acquire the position, height, inclination, shape, and the like of the substrate W based on the surface height distribution of the substrate W measured by the first measurement unit 81.

In step S107, the control unit CNT calculates the relative position (X/Y-direction, θZ-direction, and magnification components) between the mold M (the mesa portion Me) and the substrate W. More specifically, the control unit CNT calculates the relative position between the mold M (the mesa portion Me) and the substrate W based on the positional shift amount of the mesa portion Me obtained in step S102 and the positional shift amount of the substrate W obtained in step S105. The positional shift amount of the mesa portion Me obtained in step S102 and the positional shift amount of the substrate W obtained in step S105 are obtained based on the mark 35a (that is, the stage coordinate system) on the reference plate 35 in the substrate holding unit 30 as a common reference. Accordingly, the control unit CNT can perform control by calculating the relative position between the mesa portion Me and the substrate W based on the positional shift amount of the mesa portion Me and the positional shift amount of the substrate W. The control unit CNT calculates the relative position between the mold M (the mesa portion Me) and the substrate W based on the surface height distribution of the mold M obtained in step S103 and the surface height distribution of the substrate W obtained in step S106. The control unit CNT may adjust the relative position between the mold M and the substrate W so as to set the relative position, height, inclination, and shape between the mold M (the mesa portion Me) and the substrate W to desired states based on the surface height distribution of the mold M and the surface height distribution of the substrate W.

In step S108, the control unit CNT supplies the imprint material 91 onto the substrate W (pattern formation region) (supply step). For example, the control unit CNT causes the supply unit 90 to discharge an imprint material in the form of a plurality of droplets while causing the substrate holding unit 30 to move the substrate W in the X and Y directions below the supply unit 90. At this time, the control unit CNT controls the movement of the substrate W based on the relative position between the mold M and the substrate W calculated in step S107. This makes it possible to supply the imprint material in the form of a plurality of droplets onto the substrate W.

In step S109, the control unit CNT forms the pattern of the mesa portion Me of the mold M on the imprint material on the substrate W (pattern formation step). More specifically, the control unit CNT causes the substrate holding unit 30 to place the substrate W below the mold M and then aligns the mold M (the mesa portion Me) with the substrate W (pattern formation region) while causing the second detection unit 72 to detect the relative position between the mark 23 on the mold M and the mark on the substrate W. The control unit CNT causes the mold holding unit 20 to bring the mold M into contact with the imprint material on the substrate W by causing the mold holding unit 20 to move the mold M in the -Z direction and then causes the light irradiation unit 10 to irradiate the imprint material 91 with light in this state to cure the imprint material. Upon curing the imprint material, the control unit CNT releases the mold M from the cured imprint material 91 on the substrate W by causing the mold holding unit 20 to move the mold M in the +Z direction. This makes it possible to form, on the substrate W, the cured product of the imprint material 91 onto which the pattern of the mesa portion Me of the mold M is transferred.

In this case, in step S109, the control unit CNT may adjust the relative height or inclination between the mold M (the mesa portion Me) and the substrate W based on the relative height or inclination between the mold M (the mesa portion Me) and the substrate W calculated in step S107. It is possible to adjust the relative height or inclination between the mold M (the mesa portion Me) and the substrate W by using the mold holding unit 20 and/or the substrate holding unit 30. The control unit CNT may cause the mold magnification correction mechanism (not shown) provided on the mold holding unit 20 to perform correction of the shape of the mold M (magnification correction) based on the relative shape between the mold M (the mesa portion Me) and the substrate W calculated in step S107.

In step S110, the control unit CNT causes the substrate transfer mechanism (not shown) to unload the substrate W from the substrate holding unit 30. In step S111, the control unit CNT determines whether there is the substrate W (the next substrate W) for which imprint processing is to be performed next. If there is the next substrate W, the process advances to step S104, and the control unit CNT executes steps S104 to S110 with respect to the next substrate W. If there is not the next substrate W, the process advances to step S112, and the control unit CNT causes the mold transfer mechanism (not shown) to unload the mold M from the mold holding unit 20.

### Offset of Second Measurement Unit

In the imprint apparatus 100, an offset may have occurred in the second measurement unit 82. The offset of the second measurement unit 82 can originate from a state in which the second measurement unit 82 is attached to the stage 32 at a position offset from a predetermined position (attachment error) and/or a state in which an optical member is incorporated in the second measurement unit 82 at a position offset from a predetermined position (optical axis shift). The occurrence of such an offset of the second measurement unit 82 will cause a measurement error corresponding to the offset in the measurement result obtained by the second measurement unit 82. This makes it difficult for the second measurement unit 82 to accurately measure the surface height distribution of the mold M in step S103 described above. That is, it can be difficult to accurately form the pattern of the imprint material on the substrate.

Accordingly, in the present embodiment, adjustment processing is performed for the imprint apparatus 100. The adjustment processing for the imprint apparatus 100 can include the processing of determining the offset of the second measurement unit 82. The adjustment processing may be understood as further including the processing of reflecting the offset in the measurement of the surface height distribution of the mold M by the second measurement unit 82 (step S103). The offset may be reflected by correcting the measurement result obtained by the second measurement unit 82 with the offset or correcting the movement of the stage 32 during the measurement of the surface height distribution of the mold M by the second measurement unit 82 with the offset. For example, the control unit CNT can control the movement of the stage 32 so as to reduce the measurement error of the second measurement unit 82 based on the offset of the second measurement unit 82.

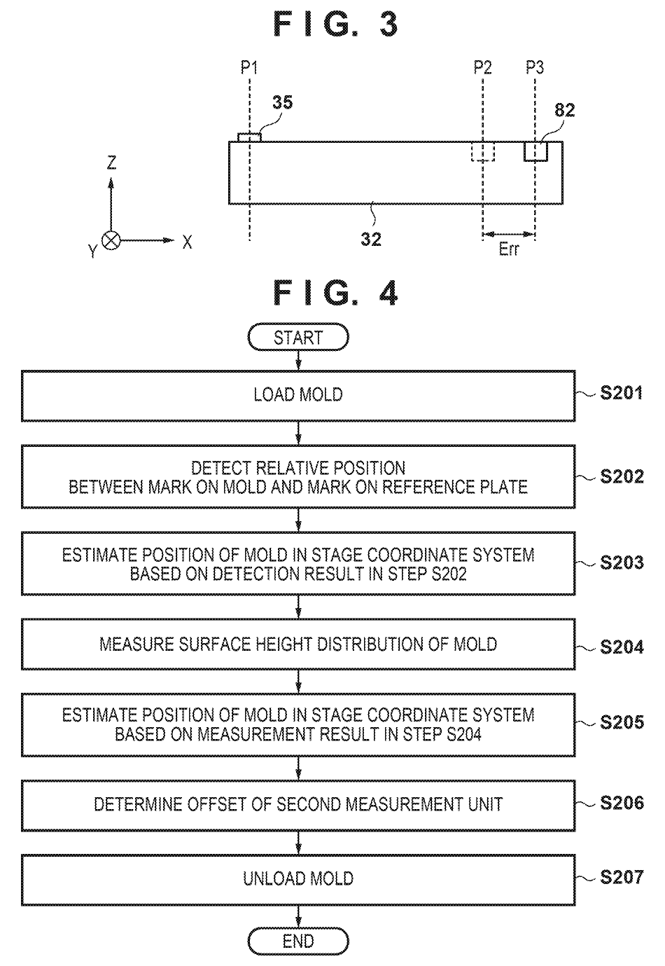

FIG. 3 is a view for explaining the offset of the second measurement unit 82. FIG. 3 shows the stage 32 of the substrate holding unit 30, the reference plate 35, and the second measurement unit 82. When the second measurement unit 82 measures the surface height distribution of the mold M, the value obtained by adding various errors such as the above attachment error and optical axis shift can occur as the positional shift of the second measurement unit 82 in the X and Y directions. Such a positional shift of the second measurement unit 82 is expressed as an error Err between an ideal position P2 and an attachment position P3 of the second measurement unit 82 on the stage 32. The error Err is the offset of the second measurement unit 82. In this case, the error Err may be understood as the error between the ideal position P2 and the attachment position P3 of the second measurement unit 82 with reference to a position P1 of the reference plate 35. The ideal position P2 is the position at which the second measurement unit 82 should be placed on the stage 32, that is, with reference to the position P1 of the reference plate 35. The attachment position P3 is the position at which the second measurement unit 82 is actually attached on the stage 32, that is, with reference to the position P1 of the reference plate 35.

Adjustment processing (adjustment method) for the imprint apparatus 100 according to the present embodiment will be described below. FIG. 4 is a flowchart showing adjustment processing for the imprint apparatus 100 according to the present embodiment. The control unit CNT can execute the adjustment processing shown in the flowchart of FIG. 4 by comprehensively controlling the respective units of the imprint apparatus 100. Adjustment processing can be executed before imprint processing but may be periodically executed.

In this case, the adjustment member held by the mold holding unit 20 to perform adjustment processing is not limited to the mold M applied to imprint processing. The adjustment member can be held by the mold holding unit 20 and can be a member configured to have a feature portion configured by a stepped portion and an alignment mark. This feature portion may be a portion corresponding to the mesa portion Me of the mold M or may have a shape mimicking the mesa portion Me. In addition, the positional relationship between the feature portion of the adjustment member and the alignment mark is known information (for example, design information) and acquired in advance. The following will exemplify a case where the mold M applied to imprint processing is used as an adjustment member.

In step S201, the control unit CNT causes the mold transfer mechanism (not shown) to load the mold M into the mold holding unit 20 and causes the mold holding unit 20 (the mold chuck 21) to hold the mold M.

In step S202, the control unit CNT moves the stage 32 of the substrate holding unit 30 so as to place the reference plate 35 below the mold M held by the mold holding unit 20. The control unit CNT then causes the second detection unit 72 to detect the relative position between the mark 23 on the mold M held by the mold holding unit 20 and the mark 35a on the reference plate 35.

In step S203, the control unit CNT estimates the position of the mold M in the stage coordinate system based on the detection result obtained in step S202. For example, the control unit CNT estimates the position of the mesa portion Me (feature portion) of the mold M in the stage coordinate system based on the relative position between the mark 23 on the mold M detected by the second detection unit 72 in step S202 and the mark 35a on the reference plate 35. In this case, the positional relationship between the mark 23 on the mold M and the mesa portion Me is guaranteed, and the corresponding information is acquired in advance by the control unit CNT. In addition, the position of the reference plate 35 (the mark 35a) with respect to the stage 32 is also guaranteed, and the corresponding information is acquired in advance by the control unit CNT. This enables the control unit CNT to estimate the position of the mesa portion Me (feature portion) of the mold M in the stage coordinate system from the relative position between the mark 23 on the mold M detected by the second detection unit 72 and the mark 35a on the reference plate 35.

In step S204, the control unit CNT causes the second measurement unit 82 to measure the surface height distribution of the mold M. More specifically, the control unit CNT causes the second measurement unit 82 to detect the distance to the surface of the mold M (the surface height of the mold M) while moving the second measurement unit 82 in the X and Y directions with respect to the mold M by moving the substrate holding unit 30 (the stage 32) in the X and Y directions. This enables the second measurement unit 82 to measure the surface height distribution of the mold M.

In step S205, the control unit CNT estimates the position of the mold M in the stage coordinate system based on the measurement result obtained in step S204. For example, the control unit CNT estimates the position of the mesa portion Me (feature portion) of the mold M in the stage coordinate system based on the surface height distribution of the mold M measured by the second measurement unit 82 in step S204.

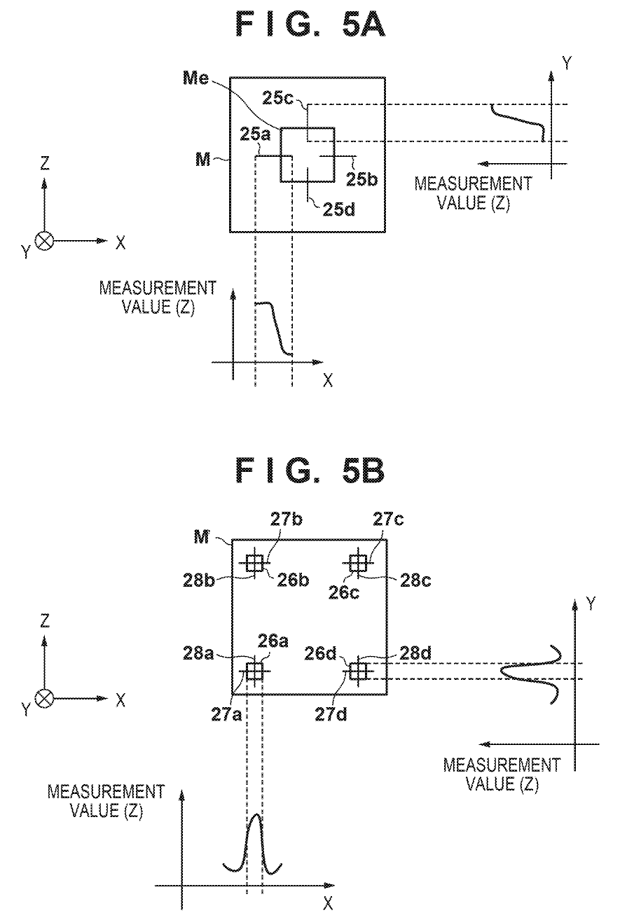

In this case, the surface height distribution of the mold M measured by the second measurement unit 82 in step S204 may include measurement target lines (measurement target positions) 25a to 25d shown in FIG. 5A. FIG. 5A is a view when the mold M held by the mold holding unit 20 is seen from below (-Z direction). The measurement target lines 25a and 25b indicate lines (positions) for the measurement of a surface height distribution in the X direction by the second measurement unit 82 and are set so as to cross edges of the mesa portion Me of the mold M. The measurement target lines 25a and 25b are respectively set as lines extending in the X direction so as to cross the X-direction sides of the mesa portion Me. The measurement target lines 25a and 25b may be parallel to each other. In contrast to this, the measurement target lines 25c and 25d indicate lines (positions) for the measurement of a surface height distribution in the Y direction by the second measurement unit 82 and are set so as to cross edges of the mesa portion Me of the mold M. The measurement target lines 25c and 25d are set as lines extending in the Y direction so as to cross the Y-direction sides of the mesa portion Me. The measurement target lines 25c and 25d may be parallel to each other.

In step S204, the second measurement unit 82 can measure the surface height distribution of the mold M in each of two directions (the X and Y directions) orthogonal to each other in a plane parallel to the surface of the mold M (the mesa portion Me). With this operation, in step S205, the control unit CNT can estimate the positions of the mesa portion Me in the X and Y directions in the stage coordinate system based on the X-direction surface height distribution and the Y-direction surface height distribution measured by the second measurement unit 82.

As shown in FIG. 5B, in adjustment processing, an adjustment member M’ having engraved concave portions (stepped portions) 26a to 26d may be used. FIG. 5B is a view when the adjustment member M’ held by the mold holding unit 20 is seen from below (the -Z direction). The depth of each of the concave portions 26a to 26d is preferably about 20 nm to 200 nm but may be about 1 μm. In this case, the surface height distribution of the adjustment member M’ measured by the second measurement unit 82 in step S204 may include measurement target lines (measurement target positions) 27a to 27d and 28a to 28d shown in FIG. 5B. The measurement target lines 27a to 27d indicate lines (positions) for the measurement of a surface height distribution in the X direction by the second measurement unit 82 and are respectively set as lines extending in the X direction so as to cross the concave portions 26a to 26d. In contrast to this, the measurement target lines 28a to 28d indicate lines (positions) for the measurement of a surface height distribution in the Y direction by the second measurement unit 82 and are respectively set as lines extending in the Y direction so as to cross the concave portions 26a to 26d.

As described above, in a case where the adjustment member M’ including the concave portions 26a to 26d is used, the second measurement unit 82 measures the surface height distribution including the measurement target lines 27a to 27d and 28a to 28d in step S204. This enables the control unit CNT to estimate the position of the adjustment member M’ in the stage coordinate system in step S205 based on the surface height distribution of the adjustment member M’ measured by the second measurement unit 82. Alternatively, the control unit CNT can estimate the positions of the concave portions 26a to 26d in the stage coordinate system as the positions of feature portions of the adjustment member M’ in the stage coordinate system. Note that the adjustment member M’ is provided with a mark detected by the second detection unit 72 in step S202, and the positional relationship between the mark and the concave portions 26a to 26d is guaranteed (that is, known information).

In a case where the adjustment member M’ is provided with the mesa portion Me, the position of the mesa portion Me in the stage coordinate system may be estimated. For example, in step S205, the control unit CNT can estimate the position of the mesa portion Me in the stage coordinate system as the position of a feature portion in the stage coordinate system based on the positions of the concave portions 26a to 26d in the stage coordinate system. In this case, the positional relationship between the concave portions 26a to 26d of the adjustment member M’ and the mesa portion Me is guaranteed (that is, known information). This enables the control unit CNT to estimate the position of the mesa portion Me in the stage coordinate system based on information indicating the positional relationship. Note that the concave portions 26a to 26d may be provided inside or outside the mesa portion Me. In addition, portions of the pattern provided on the adjustment member M’ or stepped portion shapes thereof can be used as the concave portions 26a to 26d.

Referring back to FIG. 4, in step S206, the control unit CNT determines the offset of the second measurement unit 82 based on the position of the mesa portion Me (feature portion) estimated in step S203 and the position of the mesa portion Me (feature portion) estimated in step S205. The position of the mesa portion Me estimated from the detection result obtained by the second detection unit 72 in step S203 and the position of the mesa portion Me estimated from the measurement result obtained by the second measurement unit 82 in step S205 are obtained with reference to the same index (stage coordinate system). This enables the control unit CNT to determine the offset of the second measurement unit 82 based on the positions of the mesa portion Me estimated in steps S203 and S205. For example, the control unit CNT can determine, as the offset of the second measurement unit 82, the difference between the position of the mesa portion Me (feature portion) estimated in step S203 and the position of the mesa portion Me (feature portion) estimated in step S205. The offset of the second measurement unit 82 determined in step S206 can be stored (held) in the storage unit. In step S207, the control unit CNT causes the mold transfer mechanism (not shown) to unload the mold M from the mold holding unit 20.

As described above, the imprint apparatus 100 according to the present embodiment performs the adjustment processing of determining the offset of the second measurement unit 82. It is possible to accurately form the pattern of an imprint material on a substrate by controlling imprint processing (that is, the measurement of the surface height distribution of the mold M by the second measurement unit 82) based on the offset of the second measurement unit 82 determined in this adjustment processing.

### Embodiment of Article Manufacturing Method

An article manufacturing method according to the embodiment of the present disclosure is suitable for manufacturing an article, for example, a microdevice such as a semiconductor device or an element having a microstructure. The article manufacturing method according to the present embodiment includes a forming step of forming a pattern on a substrate using the above-described imprint apparatus (imprint method), a processing step of processing the substrate on which the pattern is formed in the forming step, and a manufacturing step of manufacturing an article from the substrate processed in the processing step. An imprint apparatus that performs the forming step can be adjusted by using the above adjustment method. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

The pattern of a cured product formed using the above-described imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. An example of the mold is a mold for imprint.

The pattern of the cured product is directly used as the constituent member of at least some of the above-described articles or used temporarily as a resist mask. After etching or ion implantation is performed in the substrate processing step, the resist mask is removed.

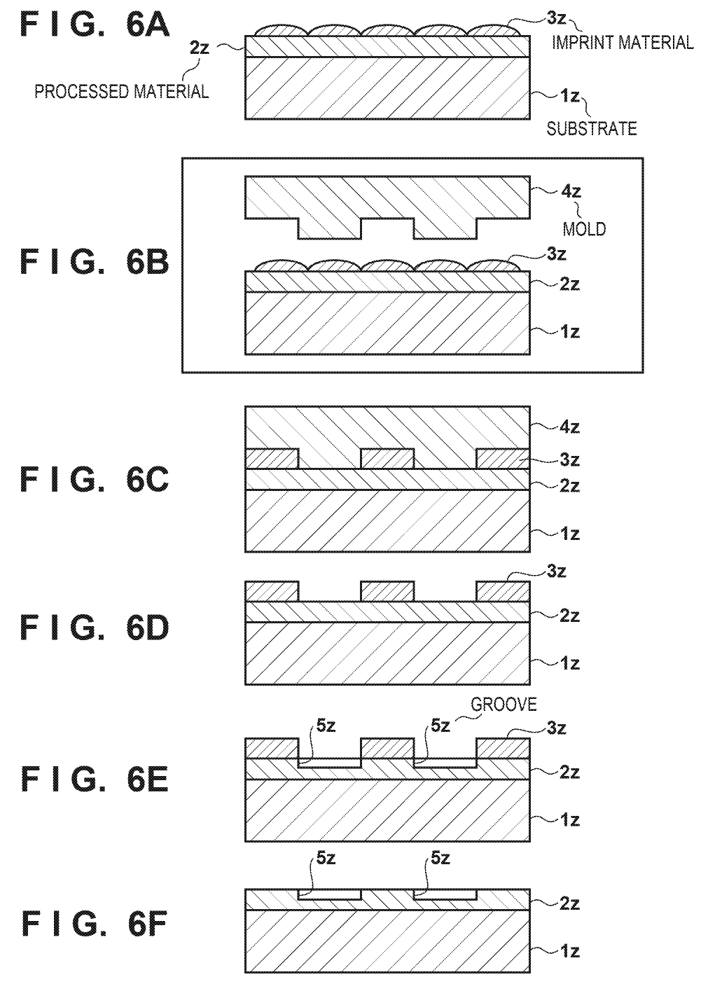

A practical manufacturing method for an article in a case where an imprint apparatus is used as the shaping apparatus will be described next. As shown in FIG. 6A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 6B, a side of a mold 4z for imprint with a concave/convex pattern is directed to face the imprint material 3z on the substrate. As shown in FIG. 6C, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

As shown in FIG. 6D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the concave/convex pattern of the mold 4z is transferred to the imprint material 3z.

As shown in FIG. 6E, when etching is performed using the pattern of the cured product as an etching resistant mask, a portion of the surface of the processed material 2z where the cured product does not exist or remains thin is removed to form a groove 5z. As shown in FIG. 6F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

1. An adjustment method for an imprint apparatus that forms a pattern to an imprint material on a substrate held by a stage, by using a mold held by a mold holder, the method comprising:
estimating a position of a member held by the mold holder, as a first position, based on a result of detecting a relative position between a mark on the member and a mark on the stage with a detector;
estimating a position of the member, as a second position, based on a result of measuring a surface height distribution of the member held by the mold holder with a measurement device; and
determining an offset of the measurement device based on the estimated first and second positions.

2. The adjustment method according to claim 1, wherein
the member includes, on a surface, a feature portion configured by a stepped portion, and
the second position of the member is estimated based on a position of the feature portion obtained from a measurement result by the measurement device.

3. The adjustment method according to claim 1, wherein
the member includes, on a surface, a feature portion which is configured by a stepped portion and whose positional relationship with the mark on the member is guaranteed,
the position of the feature portion is estimated as each of the first position and the second position, and
the offset is determined based on the position of the feature portion estimated as the first position and the position of the feature portion estimated as the second position.

4. The adjustment method according to claim 1, wherein in a case where the measurement device measures the surface height distribution of the mold held by the mold holder, movement of the stage on which the measurement device is mounted is controlled based on the determined offset.

5. The adjustment method according to claim 1, wherein a difference between the first position and the second position is determined as the offset.

6. The adjustment method according to claim 1, wherein the second position is estimated based on a result of measuring the surface height distribution of the member in each of two directions orthogonal to each other within a plane parallel to a surface of the member with the measurement device.

7. The adjustment method according to claim 1, wherein the mark on the stage is provided on a reference plate fixed to the stage.

8. An imprint method comprising:
adjusting an imprint apparatus by using an adjustment method defined in claim 1; and
forming a pattern on a substrate by using the adjusted imprint apparatus.

9. An article manufacturing method comprising:
processing a substrate on which a pattern is formed by using an imprint method defined in claim 8; and
manufacturing an article from the processed substrate.

10. An imprint apparatus that forms a pattern to an imprint material on a substrate by using a mold, the apparatus comprising:
a mold holder configured to hold the mold;
a stage configured to hold the substrate;
a detector configured to detect a relative position between a mark on the mold and a mark on the substrate;
a measurement device configured to measure a surface height distribution of the mold; and
a controller configured to
estimate a position of a member held by the mold holder, as a first position, based on a result of detecting a relative position between a mark on the member and a mark on the stage with the detector,
estimate a position of the member, as a second position, based on a result of measuring a surface height distribution of the member held by the mold holder with the measurement device, and
determine an offset of the measurement device based on the estimated first and second positions.
